(19) United States
(12) Patent Application Publication
(10) Pub. No.: US 2026/0075805 A1
(43) Pub. Date: Mar. 12, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventors: Yusuke MIKI, Yokkaichi Mie (JP); Kazuhiro KATONO, Mie Mie (JP); Yusuke MUTO, Yokkaichi Mie (JP); Tomoki HARADA, Yokkaichi Mie (JP); Jiro HATANO, Yokkaichi Mie (JP); Yurika SERIZAWA, Yokkaichi Mie (JP); Akifumi GAWASE, Kuwana Mie (JP)

(21) Appl. No.: 19/070,365

(22) Filed: Mar. 4, 2025

(30) Foreign Application Priority Data
Sep. 10, 2024 (JP) 2024-156644

(51) Int. Cl. H10B 12/00

(52) U.S. Cl. CPC H10B 12/33; H10B 12/036; H10B 12/05

(57) ABSTRACT

According to one embodiment, a semiconductor device includes: a first electrode containing silicon; a second electrode that contacts an upper surface of the first electrode; a third electrode that is provided above the second electrode; an oxide semiconductor that contacts an upper surface of the second electrode and extends in a first direction from the second electrode toward the third electrode; an insulating film that is provided on a side surface of the oxide semiconductor; and a first conductor that contacts at least a part of the insulating film, in which the second electrode includes a second conductor that contains a conductive oxide and contacts a lower surface of the oxide semiconductor, and a third conductor that is provided between the second conductor and the first electrode and contains a compound having titanium and silicon.

### CROSS-REFERENCE TO RELATED APPLICATION(S)

This application is based upon and claims the benefit of priority from Japanese Patent Application No. 2024-156644, filed Sep. 10, 2024, the entire contents of which are incorporated herein by reference.

### FIELD

Embodiments described herein relate generally to a semiconductor device and a method of manufacturing a semiconductor device.

### BACKGROUND

Semiconductor devices using capacitors and transistors are known.

### BRIEF DESCRIPTION OF THE DRAWINGS

FIG. 1 is a block diagram illustrating an example of a configuration of a memory system including a semiconductor device according to an embodiment.

FIG. 2 is a circuit diagram illustrating an example of a circuit configuration of a memory cell array in the semiconductor device according to the embodiment.

FIG. 3 is a plan view illustrating an example of a planar layout of the memory cell array in the semiconductor device according to the embodiment.

FIG. 4 is a cross-sectional view taken along line IV-IV in FIG. 3 and illustrating an example of a cross-sectional structure of the memory cell array in the semiconductor device according to the embodiment.

FIG. 5 is a cross-sectional view taken along line V-V in FIG. 3 and illustrating an example of a cross-sectional structure of the memory cell array in the semiconductor device according to the embodiment.

FIG. 6 is a cross-sectional view illustrating an example of a structure of a lower electrode of a transistor in the semiconductor device according to the embodiment.

FIGS. 7-9 are each a cross-sectional view illustrating an example of a method of manufacturing the semiconductor device according to the embodiment.

### DETAILED DESCRIPTION

Embodiments provide a semiconductor device with improved reliability.

In general, according to one embodiment, a semiconductor device includes: a first electrode containing silicon; a second electrode that contacts an upper surface of the first electrode; a third electrode that is provided above the second electrode; an oxide semiconductor that contacts an upper surface of the second electrode and extends in a first direction from the second electrode toward the third electrode; an insulating film that is provided on a side surface of the oxide semiconductor; and a first conductor that contacts at least a part of the insulating film, in which the second electrode includes a second conductor that contains a conductive oxide and contacts a lower surface of the oxide semiconductor, and a third conductor that is provided between the second conductor and the first electrode and contains a compound having titanium and silicon.

Hereinafter, an embodiment will be described with reference to the drawings. It should be noted that dimensions and ratios in the drawings are not necessarily the same as the actual ones. In the following description, components having substantially the same functions and configurations are denoted by the same reference signs. When components having similar configurations are distinguished from each other, different characters or numbers may be added to the same reference signs.

In the following description, when two different components are described as being connected, the two components are electrically connected. When the two components are connected, the two components may be electrically connected with a component different from the two components interposed therebetween. The components may be connected with an insulator interposed therebetween as long as the components can inter-operate electrically through the insulator.

### 1 Embodiment

A semiconductor device according to an embodiment will be described below.

### 1.1 Configuration

A configuration of the semiconductor device according to the embodiment will be described.

### 1.1.1 Memory System

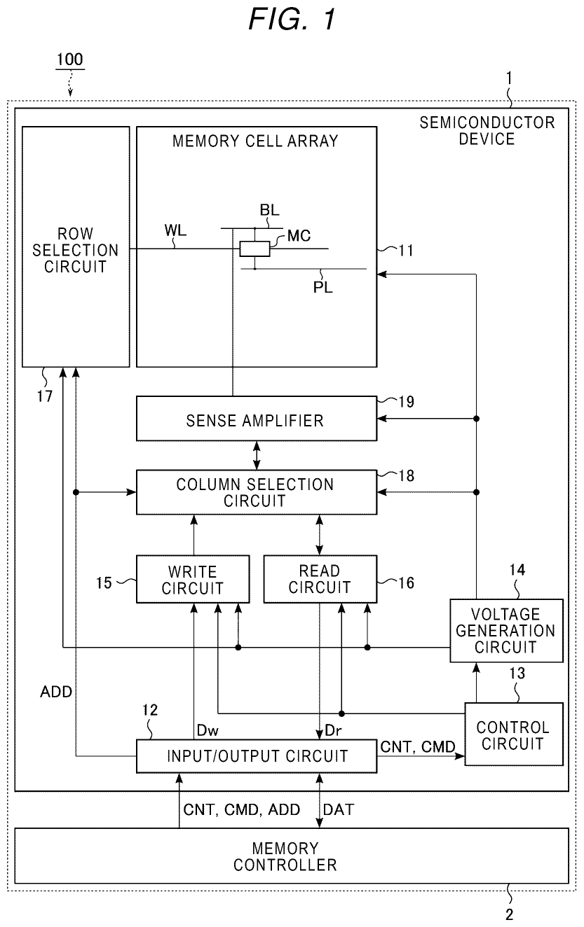

A configuration of a memory system including the semiconductor device according to the embodiment will be described with reference to FIG. 1. FIG. 1 is a block diagram illustrating an example of the configuration of the memory system including the semiconductor device according to the embodiment.

A memory system 100 executes a data write operation, a data read operation, and the like in response to commands from a host device (not illustrated) outside the memory system 100.

The memory system 100 includes a semiconductor device 1 and a memory controller 2.

The semiconductor device 1 is a memory device that uses a transistor to select a memory element. The semiconductor device 1 stores data using a capacitor, for example. The semiconductor device 1 is a dynamic random access memory (DRAM), for example. The memory controller 2 controls the semiconductor device 1.

The semiconductor device 1 includes a memory cell array 11, an input/output circuit 12, a control circuit 13, a voltage generation circuit 14, a write circuit 15, a read circuit 16, a row selection circuit 17, a column selection circuit 18, and a sense amplifier 19.

The memory cell array 11 includes a plurality of memory cells MC, a plurality of word lines WL, a plurality of bit lines BL, and a plate line PL. In FIG. 1, one memory cell MC, one word line WL, and one bit line BL are illustrated. Each of the memory cells MC stores 1-bit data. Each of the memory cells MC is connected between one bit line BL among the plurality of bit lines BL and one plate line PL. Each of the memory cells MC is connected to one word line WL among the plurality of word lines WL. The word line WL is associated with a row. The bit line BL is associated with a column. In the memory cell array 11, one memory cell MC is specified by selection of one row and selection of one column.

The input/output circuit 12 receives a control signal CNT, a command CMD, an address signal ADD, and data DAT from the memory controller 2. The input/output circuit 12 transmits data DAT to the memory controller 2. The data DAT is referred to as data to be written when data is written to the semiconductor device 1. The data DAT is referred to as read data when data is read from the semiconductor device 1.

The control circuit 13 receives the control signal CNT and the command CMD from the input/output circuit 12. The control circuit 13 instructs the write circuit 15 to write data to the semiconductor device 1 based on the control signal CNT and the command CMD. The control circuit 13 instructs the read circuit 16 to read data from the semiconductor device 1 based on the control signal CNT and the command CMD. The control circuit 13 instructs the voltage generation circuit 14 to generate a voltage based on the control signal CNT and the command CMD.

The voltage generation circuit 14 generates various voltages based on the instruction of the control circuit 13. The voltage generation circuit 14 supplies the generated voltages to the memory cell array 11, the write circuit 15, the read circuit 16, the row selection circuit 17, the column selection circuit 18, and the sense amplifier 19.

The write circuit 15 performs processing and control for writing data to the memory cell MC. The write circuit 15 receives data to be written Dw from the input/output circuit 12. The data to be written Dw is data to be written to a data-write target memory cell MC. The write circuit 15 receives one or more voltages used in a data write operation from the voltage generation circuit 14. The write circuit 15 supplies the one or more voltages used in the data write operation to the column selection circuit 18 based on control of the control circuit 13 and the data to be written Dw.

The read circuit 16 performs processing and control for reading data from the memory cell MC. The read circuit 16 receives one or more voltages used in a data read operation from the voltage generation circuit 14. The read circuit 16 determines data stored in the memory cell MC using the voltages used in the data read operation based on control of the control circuit 13. The determined data is supplied to the input/output circuit 12 as read data Dr.

The row selection circuit 17 receives the address signal ADD from the input/output circuit 12. The row selection circuit 17 supplies the voltages received from the voltage generation circuit 14 to the memory cell array 11. Accordingly, the row selection circuit 17 sets one word line WL associated with a row specified by the received address signal ADD to a selected state.

The column selection circuit 18 receives the address signal ADD from the input/output circuit 12. The column selection circuit 18 supplies the voltages received from the voltage generation circuit 14 to the memory cell array 11. Accordingly, the column selection circuit 18 sets the bit line BL associated with a column specified by the received address signal ADD to a selected state.

The sense amplifier 19 uses the voltages received from the voltage generation circuit 14 to amplify the voltage on the bit line BL to determine the data stored in the data-read target memory cell MC during the data read operation.

### 1.1.2 Circuit Configuration of Memory Cell Array

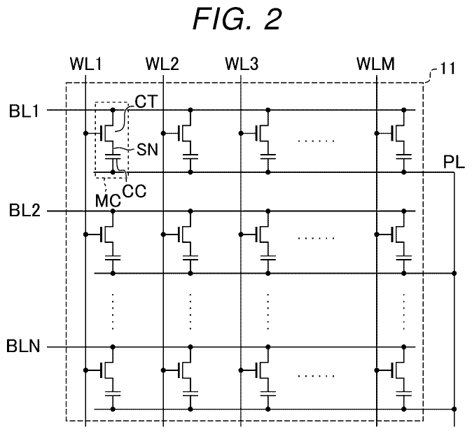

A circuit configuration of the memory cell array in the semiconductor device according to the embodiment will be described with reference to FIG. 2. FIG. 2 is a circuit diagram illustrating an example of the circuit configuration of the memory cell array in the semiconductor device according to the embodiment.

The memory cell array 11 includes M word lines WL (WL1 to WLM), N bit lines BL (BL1 to BLN), and the plate line PL. M and N are positive integers.

Each of the plurality of bit lines BL is connected to, for example, M memory cells MC corresponding to the bit line BL among the plurality of memory cells MC. The M memory cells MC corresponding to the bit line BL correspond to each of M word lines WL, for example.

Each of the memory cells MC includes a cell capacitor CC and a cell transistor CT.

The cell transistor CT is, for example, an n-type metal oxide semiconductor field effect transistor (MOSFET). Hereinafter, one of a source and a drain of the cell transistor CT is simply referred to as one end of the cell transistor CT, and the other is simply referred to as the other end of the cell transistor CT. One end of each of the cell transistors CT is connected to one bit line BL corresponding to the cell transistor CT. A gate of each of the cell transistors CT is connected to one word line WL corresponding to the cell transistor CT.

A semiconductor as a part of the cell transistor CT includes a region where a channel is formed (channel region). Materials of semiconductor include an oxide semiconductor. The materials of the semiconductor are formed of an oxide semiconductor. When a material is formed of a composition A, the material may include unintended impurities different from the composition A.

The cell capacitor CC is a capacitive element. One end electrode of each of the cell capacitors CC is connected to the other end of the cell transistor CT corresponding to the cell capacitor CC. The other electrode of each of the cell capacitors CC is connected to the plate line PL. The cell capacitor CC stores data based on an electric charge stored in a node connected to the cell transistor CT. Hereinafter, the node is also referred to as a storage node SN.

A quantity of the electric charge stored in the storage node SN is used to specify a state in which the memory cell MC stores data of “1” or a state in which the memory cell MC stores data of “0”. Hereinafter, as an example, a state in which a potential of the storage node SN is charged to a potential of the plate line PL or relatively higher is regarded as the state in which the memory cell MC stores the data of “1”. A state in which the potential of the storage node SN is charged to a potential relatively lower than a potential of the plate line PL is regarded as the state in which the memory cell MC stores the data of “0”.

According to the above-described configuration, the cell capacitor CC and the cell transistor CT in each of the memory cells MC are connected in series between the bit line BL corresponding to the memory cell MC and the plate line PL.

### 1.1.3 Planar Layout of Memory Cell Array

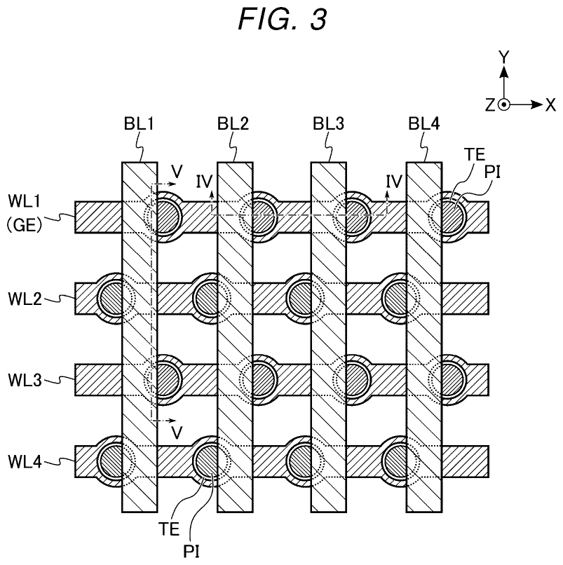

A planar layout of the memory cell array 11 in the semiconductor device 1 according to the embodiment will be described with reference to FIG. 3. FIG. 3 is a plan view illustrating an example of a planar layout of the memory cell array in the semiconductor device according to the embodiment. FIG. 3 illustrates four word lines WL1 to WL4 and four bit lines BL1 to BL4 as an example.

In the following description, an X direction is a direction substantially parallel to a substrate of the semiconductor device 1. The X direction corresponds to an extension direction of the word line WL. A Y direction is a direction substantially parallel to the substrate of the semiconductor device 1 and orthogonal to the X direction. The Y direction corresponds to an extension direction of the bit line BL. A Z direction is a direction substantially perpendicular to the substrate. In the Z direction, a side from the substrate toward the memory cell array 11 is called an upper side. In the Z direction, a side from the memory cell array 11 toward the substrate is called a lower side. In two surfaces of a certain component in which the two surfaces are perpendicular to the Z direction, the surface on the upper side is called an upper surface, and the surface on the lower side is called a lower surface.

The memory cell array 11 includes a plurality of pillars PI and a plurality of upper electrodes TE associated with the plurality of bit lines BL and the plurality of word lines WL. Each of the pillars PI functions as, for example, one vertical transistor. Each of the pillars PI corresponds to the cell transistor CT. In the embodiment, a plurality of gate electrodes GE function as the word lines WL, respectively.

FIG. 3 illustrates four sets including a row of pillars PI. Each of the four sets including a row of pillars PI corresponds to the word lines WL1 to WL4, respectively. Four pillars PI are arranged in the X direction in each row. Eight pillars PI in each set including two adjacent rows of pillars PI have the same arrangement, for example. Positions of four pillars PI in one row of the set including two adjacent rows of pillars PI are different in the X direction from positions of four pillars PI in the other row. According to the above arrangement, in the set including two adjacent rows of pillars PI, four pillars PI in one row are shifted from four pillars PI in the other row in the X direction. FIG. 3 illustrates a case in which each of the four sets including a row of pillars PI includes four pillars PI, but the number of rows of pillars PI and the number of pillars PI in one row are not limited thereto. The number of rows of pillars PI and the number of pillars in one row can be changed as appropriate.

Each of the pillars PI and the bit line BL corresponding to each of the pillar PI are connected to each other via the upper electrode TE. Each of the plurality of bit lines BL extends in the Y direction. The plurality of bit lines BL are arranged in the X direction. Hereinafter, a side closer to the bit line BL1 of the bit lines BL1 and BL4 is referred to as one end side in the X direction. A side closer to the bit line BL4 of the bit lines BL1 and BL4 is referred to as the other end side in the X direction. Each of the bit lines BL overlaps at least a part of one pillar PI of each set including rows of pillars PI when viewed in the Z direction. Each of the bit lines BL overlaps, for example, one end side of the pillar PI included in a row corresponding to the word line WL1 or WL3 (included in an odd-numbered row) in the X direction. The same bit line BL overlaps, for example, the other end side of the pillar PI included in a row corresponding to the word line WL2 or WL4 (included in an even-numbered row) in the X direction.

Each of the bit lines BL is electrically connected to each of the pillars PI overlapping the bit line BL. The number of pillars PI overlapping each of the bit lines BL can be designed to be any number depending on the number of word lines WL.

Each of the gate electrodes GE (word lines WL) extends in the X direction as described above. The plurality of gate electrodes GE are arranged in the Y direction. Each of the gate electrodes GE surrounds a periphery of each of the pillars PI corresponding to the gate electrode GE when viewed in the Z direction.

### 1.1.4 Cross-Sectional Structure of Memory Cell Array

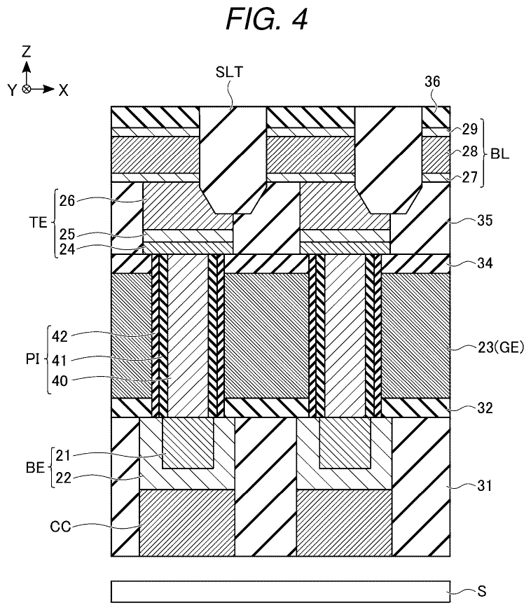

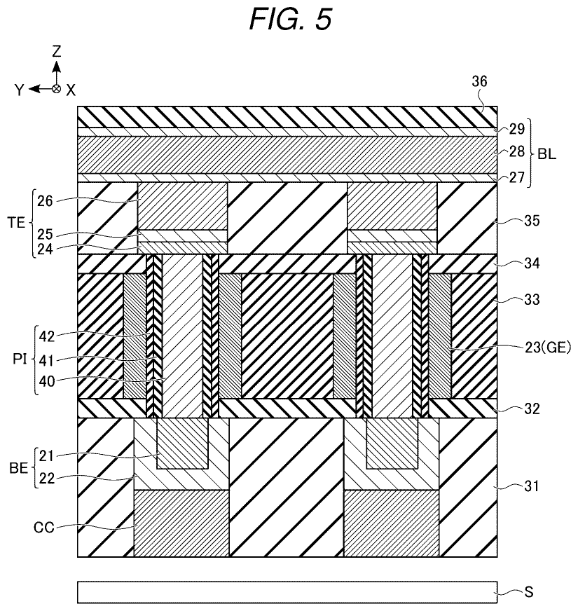

A cross-sectional structure of the memory cell array 11 in the semiconductor device 1 according to the embodiment will be described with reference to FIGS. 4 and 5. FIG. 4 is a cross-sectional view taken along line IV-IV in FIG. 3 and illustrating an example of a cross-sectional structure of the memory cell array in the semiconductor device according to the embodiment. FIG. 5 is a cross-sectional view taken along line V-V in FIG. 3 and illustrating an example of a cross-sectional structure of the memory cell array in the semiconductor device according to the embodiment.

The memory cell array 11 includes a plurality of conductors 21 to 29, insulators 31 to 36, a plurality of oxide semiconductors 40, a plurality of gate insulating films 41 and 42, and a member SLT.

The insulator 31 is provided above a substrate S.

One end electrode of each of the plurality of cell capacitors CC is provided in the same layer as the insulator 31. Hereinafter, the one end electrode of the cell capacitor CC is also simply referred to as the cell capacitor CC. The plurality of cell capacitors CC contain a material with conductivity. The material includes, for example, silicon (Si). The material is, for example, silicon germanium (SiGeₓ₁). The value x1 is a positive number. The plurality of cell capacitors CC have, for example, a columnar shape extending in the Z direction. The shape of the columnar shape in an XY cross section is not particularly limited, and may be, for example, a circular shape or a rectangular shape.

In the same layer as the insulator 31, the plurality of conductors 21 are provided corresponding to the plurality of cell capacitors CC and above the plurality of cell capacitors CC. The plurality of conductors 21 contain conductive oxide, for example. The plurality of conductors 21 contain, for example, oxygen (O) and at least one metal element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo). The plurality of conductors 21 contain, for example, indium (In), tin (Sn), and oxygen (O). The plurality of conductors 21 contain, for example, indium tin oxide (ITO). On a lower surface and a side surface of each of the conductors 21, the conductor 22 is provided corresponding to the conductor 21. Upper surfaces of the plurality of conductors 21 and 22 are flush with an upper surface of the insulator 31. A lower surface of each of the conductors 22 contacts an upper surface of the cell capacitor CC corresponding to the conductor 22. A set including the conductors 21 and 22 corresponding to each other functions as a lower electrode BE. The configuration of the plurality of conductors 22 will be described below in detail.

On the upper surface of the insulator 31 and the upper surfaces of the plurality of conductors 21 and 22, the insulators 32, 33, and 34 are provided upwardly in this order.

The plurality of oxide semiconductors 40 are provided corresponding to the plurality of conductors 21 and 22. Each of the oxide semiconductors 40 is provided on the upper surface of the conductor 21 corresponding to the oxide semiconductor 40. Each of the oxide semiconductors 40 is provided such that an entire lower surface of the oxide semiconductor 40 contacts the upper surface of the conductor 21. The plurality of oxide semiconductors 40 penetrate the insulators 32 to 34. The plurality of oxide semiconductors 40 are, for example, oxide semiconductors. The plurality of oxide semiconductors 40 contain, for example, zinc (Zn) and at least one element among indium (In), gallium (Ga), silicon (Si), aluminum (Al), and tin (Sn). The oxide semiconductor 40 contains, for example, indium-gallium-zinc oxide.

According to the above-described configuration, the conductor 21 corresponding to the oxide semiconductor 40 is provided between the oxide semiconductor 40 and the conductor 22 corresponding to the oxide semiconductor 40. In such configuration, the conductor 21 is provided such that contact resistance between the conductor 22 and the oxide semiconductor 40 is reduced.

The gate insulating film 41 is provided on a side surface of each of the oxide semiconductors 40. The gate insulating film 41 contains, for example, an insulator such as silicon oxide. The gate insulating film 42 is provided on a side surface of each of the gate insulating films 41. The gate insulating film 42 contains, for example, an insulator such as silicon nitride. At least one layer of gate insulating film may be provided on the side surface of each of the oxide semiconductors 40. Namely, the memory cell array 11 may include just one of the gate insulating films 41 and 42.

A set including the oxide semiconductor 40 and the gate insulating films 41 and 42 corresponding to each other functions as the pillar PI. Each of the oxide semiconductors 40 is equivalent to a semiconductor that forms a part of the cell transistor CT. The upper surfaces of the plurality of oxide semiconductors 40 and the upper surfaces of the plurality of gate insulating films 41 and 42 are flush with the upper surfaces of the insulators 34.

The pillar PI may have a tapered shape. The pillar PI may have a bow shape in which a central portion in the Z direction bulges.

The plurality of conductors 23 are provided in the same layer as the insulator 33. Each of the conductors 23 functions as the gate electrode GE (word line WL). Each of the plurality of conductors 23 extends in the X direction corresponding to the gate electrode GE. Thus, in an XZ cross section illustrated in FIG. 4, the conductors 23 contact with the side surfaces of the plurality of pillars PI arranged in the X direction, respectively. The plurality of conductors 23 are arranged in the Y direction corresponding to the plurality of gate electrodes GE. Thus, in a YZ cross section illustrated in FIG. 5, each of the conductors 23 contacts the side surface of one pillar PI corresponding to the conductor 23.

The insulator 35 is provided on the upper surface of the insulator 34, the upper surfaces of the plurality of oxide semiconductors 40, and the upper surfaces of the gate insulating films 41 and 42.

The plurality of conductors 24 are provided corresponding to the plurality of pillars PI in the same layer as the insulator 35. Each of the conductors 24 is provided on the upper surface of the oxide semiconductor 40 of the pillar PI corresponding to the conductor 24. Each of the conductors 24 covers the upper surface of the oxide semiconductor 40 corresponding to the conductor 24. The plurality of conductors 24 contain, for example, conductive oxide. The plurality of conductors 24 contain, for example, oxygen (O) and at least one metal element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo). The plurality of conductors 24 contain, for example, oxide of at least one of indium (In) or tin (Sn). The conductive oxide includes, for example, at least one compound of indium tin oxide and tin oxide.

The plurality of conductors 25 are provided corresponding to the plurality of conductors 24 and on upper surfaces of the plurality of conductors 24. The plurality of conductors 25 contain, for example, at least one element selected from titanium (Ti), tin (Sn), zinc (Zn), ruthenium (Ru), and niobium (Nb). The plurality of conductors 25 contain, for example, nitride of the at least one element among these elements. The plurality of conductors 25 contain, for example, titanium nitride (TiN).

The plurality of conductors 26 are provided corresponding to the plurality of conductors 25 and on upper surfaces of the plurality of conductors 25. The plurality of conductors 26 contain, for example, tungsten (W). Upper surfaces of the plurality of conductors 26 are flush with the upper surface of the insulator 35. A thickness in the Z direction of each of the plurality of conductors 26 is, for example, thicker than a thickness of each of the plurality of conductors 24 and 25.

In the above-described configuration, a set including the conductors 24 to 26 corresponding to each other functions as an upper electrode TE. Each of the conductors 25 prevents the metal element contained in the conductor 26 corresponding to the conductor 25 from entering the conductor 24 due to diffusion. Therefore, the plurality of conductors 25 can function as a barrier metal, for example.

The plurality of conductors 27 are provided corresponding to the plurality of upper electrodes TE on the upper surface of the insulator 35 and the upper surfaces of the plurality of conductors 26. Each of the conductors 27 is provided to contact with the conductor 26 of the plurality of upper electrodes TE corresponding to the conductor 27. Each of the conductors 27 extends in the Y direction to correspond to the bit line BL. The plurality of upper electrodes TE corresponding to each of the conductors 27, correspond to the plurality of word lines WL different from each other. The plurality of conductors 27 are arranged in the X direction corresponding to the plurality of bit lines BL. The plurality of conductors 27 contain, for example, titanium nitride (TiN).

The conductor 28 is provided on the upper surface of each of the conductors 27 corresponding to the conductor 27. The plurality of conductors 28 contain, for example, tungsten (W).

The conductor 29 is provided on the upper surface of each of the conductors 28 corresponding to the conductor 28. The plurality of conductors 29 contain, for example, titanium nitride (TiN).

In the above-described configuration, the conductors 27, 28, and 29 corresponding to each other function as the bit lines BL. The plurality of conductors 27 and 29 prevent the metal element contained in the plurality of conductors 28 from entering layers below the plurality of conductors 27 and layers above the plurality of conductors 29 due to diffusion. Therefore, the plurality of conductors 27 and 29 can function as barrier metals, for example. The plurality of conductors 27 and 29 may not be provided in some embodiments.

The insulator 36 is provided on the upper surfaces of the plurality of conductors 29.

The plurality of members SLT are provided on the upper surface of the insulator 34. Each of the members SLT extends in the Y direction. The plurality of members SLT are arranged in the X direction. Each of the members SLT penetrates the conductors 27 to 29. An upper surface of each of the members SLT is flush with the upper surface of the insulator 36, for example. A lower surface of each of the members SLT contacts the conductor 26, for example. The lower surface of each of the members SLT only needs to reach the height of the upper surface of the insulator 35. The plurality of members SLT are insulators made of silicon oxide, for example. According to the above-described configuration, two bit lines BL adjacent to each other in the X direction are separated from each other by the member SLT corresponding to the two bit lines BL. The two bit lines BL are insulated from each other by the member SLT.

In the XZ cross section including the word line WL1 or WL3, each of the members SLT overlaps one end side in the X direction of each of the upper electrodes TE, for example. In the XZ cross section including the word line WL2 or WL4, each of the members SLT overlaps the other end side in the X direction of each of the upper electrodes TE, for example. In the XZ cross section illustrated in FIG. 4, as an example, each of the members SLT overlaps the other end side of the upper electrode TE corresponding to the member SLT.

### 1.1.5 Structure of Lower Electrode

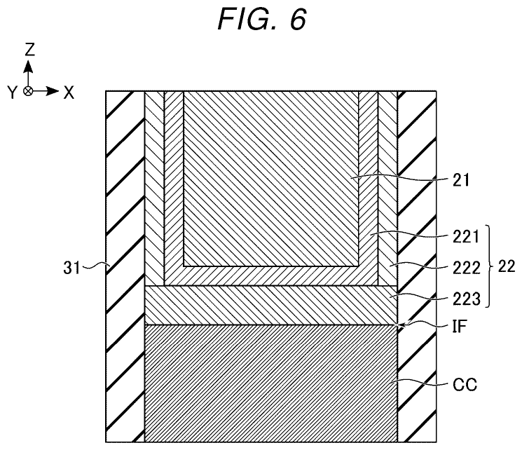

A structure of the lower electrode BE will be described below with reference to FIG. 6. FIG. 6 is a cross-sectional view illustrating an example of a structure of the lower electrode of the transistor in the semiconductor device according to the embodiment.

Each of the conductors 22 includes conductors 221, 222, and 223.

In each of the conductors 22, the conductor 221 is provided on a side surface and a lower surface of the conductor 21. The conductor 221 contains, for example, titanium nitride (TiN). The conductor 221 may further contain oxygen. The conductor 221 may further contain titanium oxide (TiO).

The conductor 222 is provided on a side surface of the conductor 221. A side surface of the conductor 222 contacts the insulator 31, for example. The conductor 222 contains, for example, titanium (Ti). The conductor 222 may further contain oxygen. The conductor 222 may further contain titanium oxide (TiO).

The conductor 223 is provided between the lower surfaces of the conductors 221 and 222 and the upper surface of the cell capacitor CC and contacts the conductors 221 and 222 and the cell capacitor CC. The conductor 223 contains, for example, titanium (Ti) and silicon (Si). The conductor 223 may contain, for example, germanium (Ge) in addition to titanium (Ti) and silicon (Si). The conductor 223 may further contain oxygen. The conductor 223 preferably contains at least one of a compound of titanium (Ti) and silicon (Si) (TiSiₓ₂) and a compound of titanium (Ti), silicon (Si), and germanium (Ge) (TiSiₓ₃Ge_{y1}). Values x2, x3, and y1 are positive numbers. The compounds can be confirmed by, for example, nano-beam diffraction method (NBD method) and electron energy loss spectroscopy (EELS).

In a manufacturing process, a conductor 223A (to be described below) formed corresponding to the conductor 223 can prevent oxide from being formed between the cell capacitor CC and the conductor 22. For example, when the cell capacitor CC contains silicon germanium, oxygen (O) contained in the conductor 21 and the oxide semiconductor 40 may be diffused, and silicon oxide (SiOₓ₃) may be formed at an interface between the cell capacitor CC and the conductor 223A. A value x3 is a positive number. The conductor 223A can prevent formation of silicon oxide. The conductors 223 and 223A may be referred to as barrier layers.

In the manufacturing process, the conductor 223A corresponding to the conductor 223 can effectively prevent the formation of silicon oxide (SiOₓ₃). As a result, it is possible to reduce a concentration C_{O} of oxygen (O) atoms at an interface (boundary) IF between the conductor 223 and the cell capacitor CC. For example, at the interface (boundary) IF between the conductor 223 and the cell capacitor CC, a concentration C_{Ti} of titanium (Ti) atoms is higher than the concentration C_{O} of oxygen (O) atoms. For example, at the interface IF, a concentration ratio C_{O}/C_{Ti} obtained by dividing the concentration C_{O} by the concentration C_{Ti} is ⅔ or less. Preferably, at the interface, the concentration ratio C_{O}/C_{Ti} is ½ or less. The concentration of a certain element can be substituted with intensity of the certain element in energy dispersive X-ray spectroscopy (EDX).

The interface IF between the conductor 223 and the cell capacitor CC is determined based on the concentration of atoms contained in the cell capacitor CC, for example. When the plurality of cell capacitors CC contain silicon germanium (SiGeₓ₁), the interface IF can be determined based on the concentration of germanium (Ge) atoms, for example. More specifically, the concentration of germanium (Ge) atoms tends to decrease toward the interface IF in the cell capacitor CC. In the embodiment, the interface IF between the conductor 223 and the cell capacitor CC can be determined as a position where the concentration of germanium (Ge) is half the maximum concentration of germanium (Ge) in the cell capacitor CC. A composition profile of atoms is acquired, for example, by a method obtained by combining observation with scanning transmission electron microscope (STEM) and energy dispersive X-ray spectroscopy (EDX) (STEM-EDX). The interface IF between the conductor 223 and the cell capacitor CC may be determined based on the concentration of silicon (Si) atoms. For example, similarly to germanium (Ge), the interface IF between the conductor 223 and the cell capacitor CC may be determined as a position where the concentration of silicon (Si) atoms is half the maximum concentration of silicon (Si) in the cell capacitor CC.

Based on reasons to be described below, when the plurality of cell capacitors CC contain silicon germanium (SiGeₓ₁), the germanium (Ge) atoms in the cell capacitor CC may have a concentration distribution in the Z direction. For example, compared to the concentration of germanium (Ge) atoms in a first portion within a first height range in the Z direction, the concentration of germanium (Ge) atoms in a second portion positioned between the first portion and the conductor 223 may be designed to be higher. Alternatively, the composition of silicon germanium in the first portion may be rich in germanium (Ge) compared to the composition of silicon germanium in the second portion.

### 1.2 Manufacturing Method

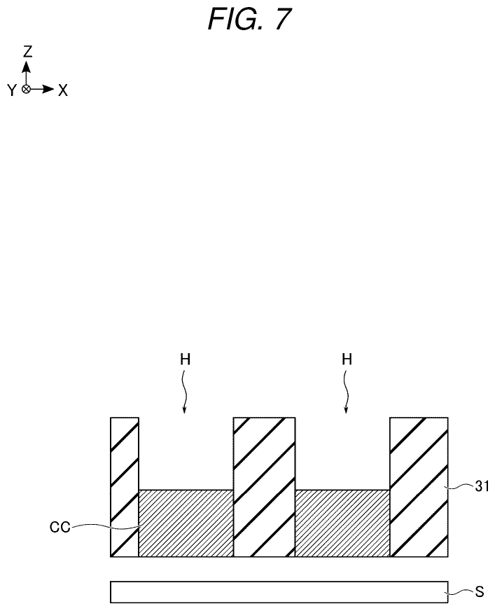

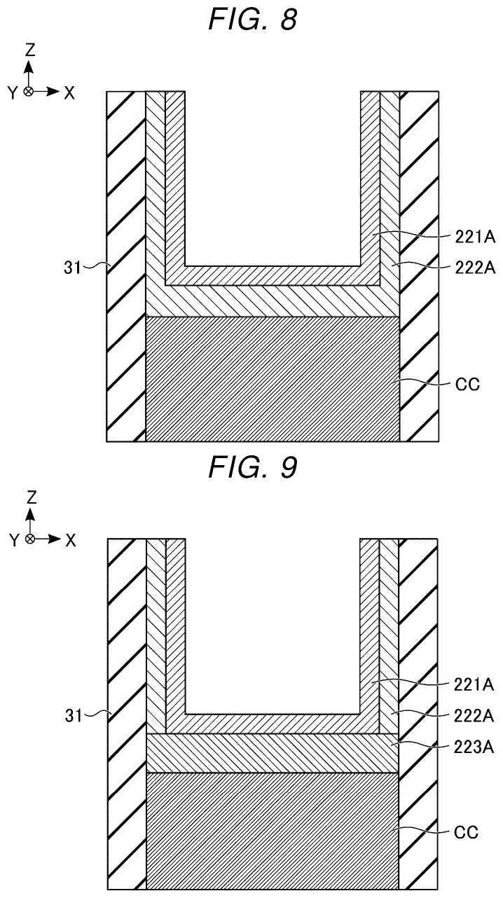

Next, a method of manufacturing the semiconductor device 1 according to the embodiment will be described with reference to FIGS. 7, 8, and 9. FIGS. 7, 8, and 9 are cross-sectional views illustrating examples of a method of manufacturing the semiconductor device according to the embodiment, respectively. The cross section illustrated in FIG. 7 corresponds to the cross section illustrated in FIG. 4. The cross sections illustrated in FIGS. 8 and 9 correspond to the cross section illustrated in FIG. 6.

First, the insulator 31 is provided above the substrate S.

Then, a plurality of holes H are formed corresponding to regions of the insulator 31 where the plurality of cell capacitors CC and the plurality of lower electrodes BE are provided. The plurality of holes H are formed using, for example, photolithography and anisotropic etching. Anisotropic etching is reactive ion etching (RIE), for example.

Then, as illustrated in FIG. 7, the plurality of cell capacitors CC are formed to be buried in the plurality of holes H, respectively.

As illustrated in FIG. 8, conductors 221A and 222A are formed on the cell capacitor CC in each of the holes H in which the cell capacitor CC is formed. The conductors 221A and 222A correspond to the conductors 221 and 222, respectively. The conductor 221A contains, for example, titanium nitride (TiN). The conductor 222A contains, for example, titanium (Ti). The conductors 221 and 222 contain more oxygen (O) compared to the conductors 221A and 222A due to, for example, diffusion of oxygen (O) contained in the conductor 21 and the oxide semiconductor 40 to be described below. The conductors 221A and 222A may have compositions different from those of the conductors 221 and 222, respectively. More specifically, the conductor 222A is formed to cover the upper surface of the cell capacitor CC and the side surface of the insulator 31. The conductor 221A is formed to cover the surface of the conductor 222A in each of the holes H.

Then, a heat treatment is performed on the structure in which the cell capacitor CC and the conductors 221A and 222A are formed in each of the holes H. Thus, the conductor 223A is formed, as illustrated in FIG. 9, in a portion where the conductor 222A and the cell capacitor CC are in contact with each other in FIG. 8. The conductor 223A corresponds to the conductor 223. The conductor 223A contains, for example, titanium (Ti) and silicon (Si). The conductor 223A may contain, for example, germanium (Ge) in addition to titanium (Ti) and silicon (Si). Similarly to the conductors 221 and 222, the conductor 223 contains oxygen (O) due to, for example, the diffusion of oxygen (O) contained in the conductor 21 and the oxide semiconductor 40 to be described below. The conductor 223 contains more oxygen (O) compared to the conductor 223A. The conductor 223A may have a composition different from that of the conductor 223. The conductor 223A can prevent formation of silicon oxide at the interface between the cell capacitor CC and the conductor 223A, as described above.

By a subsequent heat treatment, for example, titanium (Ti) contained in the conductor 222A reacts with silicon (Si) or silicon germanium (SiGeₓ₁) contained in the cell capacitor CC, and thus as illustrated in FIG. 9, the conductor 223A containing a compound (TiSiₓ₂) or a compound (TiSiₓ₃Ge_{y1}) is formed. For example, a part of the conductor 222A in FIG. 8 before the heat treatment changes into the conductor 223A. For example, a portion of the conductor 222A in contact with the cell capacitor CC changes into the conductor 223A.

Here, when the cell capacitor CC contains silicon germanium (SiGeₓ₁), reactivity of titanium (Ti) and silicon (Si) and reactivity of titanium (Ti) and germanium (Ge) may be different from each other in the heat treatment. For example, titanium (Ti) contained in the conductor 222A reacts more easily with silicon (Si) than germanium (Ge) in the heat treatment described above. Therefore, the germanium (Ge) atoms in the cell capacitor CC may have a concentration distribution in the Z direction.

Then, after the conductor 223A is formed, the conductor 21 is formed to be embedded in the hole H in which the conductors 221A and 222A are formed. Thus, the structure of the lower electrode BE illustrated in FIG. 6 is formed. The plurality of conductors 23 to 29, the insulators 32 to 36, the plurality of oxide semiconductors 40, the plurality of gate insulating films 41 and 42, the member SLT are formed above the lower electrode BE. In the heat treatment after the conductor 21 is formed, for example, oxygen (O) contained in the conductor 21 and oxide semiconductor 40 diffuses and enters the conductors 221A, 222A, and 223A. Thus, the conductors 221A, 222A, and 223A become the conductors 221, 222, and 223, respectively. As such, the conductor 22 is formed.

In the above-described manufacturing method, the conductor 223A is formed by the heat treatment after the cell capacitor CC and the conductors 221A and 222A are formed in each of the holes H, but the method is not limited thereto. The heat treatment does not have to be performed. Namely, the conductor 223A may be formed without performing the heat treatment before formation of the conductor 21 and may be formed after the cell capacitor CC and the conductors 221A and 222A are formed in each of the holes H, for example.

### 1.3 Effects

According to the embodiment, it is possible to improve reliability of the semiconductor device. Effects of the embodiment will be described as follows.

According to the embodiment, the semiconductor device 1 includes the cell capacitor CC, the lower electrode BE, the upper electrode TE, the pillar PI, and the word line WL. The cell capacitor CC contains silicon. The lower electrode BE contacts the upper surface of the cell capacitor CC. The upper electrode TE is provided above the lower electrode BE. The pillar PI includes the oxide semiconductor 40 extending in the Z direction and the gate insulating film 42 provided on the side surface of the oxide semiconductor 40. The oxide semiconductor 40 contacts the upper surface of the lower electrode BE. The word line WL contacts the gate insulating film 42. The lower electrode BE includes the conductor 21 and the conductor 22. The conductor 21 contains a conductive oxide and contacts the lower surface of the oxide semiconductor 40. The conductor 22 is provided between the conductor 21 and the cell capacitor CC and contains titanium (Ti) and silicon (Si). According to the above-described configuration, according to the embodiment, it is possible to prevent formation of a high resistance layer between the lower electrode BE and the capacitor CC. Accordingly, it is possible to improve reliability of the semiconductor device 1.

Additionally, when there is no barrier layer in contact with the cell capacitor, application of a thermal load may cause oxygen contained in the lower electrode and the channel of the cell transistor to diffuse and enter the cell capacitor. Thus, a high-resistance silicon oxide layer may be formed between the cell capacitor and the lower electrode. Here, the resistance of the lower electrode may become too high.

According to the embodiment, it is possible to prevent formation of silicon oxide during the manufacturing process due to diffusion of oxygen.

The manufacturing process of the semiconductor device 1 according to the embodiment includes: forming the hole H in the insulator 31; forming the cell capacitor CC in the hole H; forming the lower electrode BE; and forming the cell transistor CT on the upper surface of the lower electrode BE after forming the cell capacitor CC and the lower electrode BE. Forming the lower electrode BE includes forming the conductor 223A in contact with the upper surface of the cell capacitor CC, and forming the conductor 21 above the conductor 223A to be embedded in the hole H. As described above, the cell transistor CT is formed in the manufacturing process after the conductor 223A is formed. Thus, when a thermal load is applied during a process of forming the upper electrode and the like, the conductor 223A can prevent oxygen contained in the conductor 21 of the lower electrode BE and the oxide semiconductor 40 of the cell transistor CT from entering the cell capacitor CC. For example, when the conductor 221A is formed without forming the conductor 222A on the cell capacitor CC in FIG. 8, silicon oxide may be formed at the interface between the cell capacitor CC and the conductor 221A. According to the embodiment, the conductor 223A is formed by forming the conductor 222A on the cell capacitor CC, and thus it is possible to prevent formation of oxygen between the cell capacitor CC and the conductor 22. As described above, according to the embodiment, it is possible to prevent formation of silicon oxide during the manufacturing process.

Additionally, according to the embodiment, it is possible to prevent a change in characteristics of the cell transistor CT due to diffusion of oxygen contained in the oxide semiconductor 40. Namely, it is possible to prevent a change in characteristics of the cell transistor CT due to extraction of oxygen from the channel of the cell transistor CT.

In the plurality of cell capacitors CC containing silicon germanium (SiGeₓ₁), when an upper end portion of the cell capacitor CC has a composition that is richer in germanium (Ge) than a portion adjacent to the upper end portion below the upper end portion, contact resistance can be reduced. The higher the concentration of germanium atoms in silicon germanium at the upper end portion of the cell capacitor CC, the lower the Schottky barrier at the interface between the conductor 223 and the cell capacitor CC. Thus, it is possible to reduce contact resistance between the conductor 223 and the cell capacitor CC.

### 2 Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode containing silicon;
a second electrode that contacts an upper surface of the first electrode;
a third electrode that is provided above the second electrode;
an oxide semiconductor that contacts an upper surface of the second electrode and extends in a first direction from the second electrode toward the third electrode;
an insulating film that is provided on a side surface of the oxide semiconductor; and
a first conductor that contacts at least a part of the insulating film, wherein the second electrode includes
a second conductor that contains a conductive oxide and contacts a lower surface of the oxide semiconductor, and
a third conductor that is provided between the second conductor and the first electrode and contains titanium and silicon.

2. The semiconductor device according to claim 1, wherein the first electrode contains silicon and germanium.

3. The semiconductor device according to claim 1, wherein the third conductor contains a compound of titanium and silicon.

4. The semiconductor device according to claim 3, wherein the third conductor further contains germanium.

5. The semiconductor device according to claim 2, wherein the third conductor contains a compound of titanium, silicon, and germanium.

6. The semiconductor device according to claim 2, wherein
the first electrode includes
a first portion, and
a second portion that is provided between the first portion and the second electrode, and
a concentration of germanium in the second portion is higher than a concentration of germanium in the first portion.

7. The semiconductor device according to claim 1, wherein
the second electrode further contains oxygen, and
a concentration of titanium is higher than a concentration of oxygen at an interface between the first electrode and the second electrode.

8. The semiconductor device according to claim 7, wherein a concentration ratio obtained by dividing the concentration of the oxygen by the concentration of the titanium is ⅔ or less at the interface.

9. The semiconductor device according to claim 8, wherein the concentration ratio is ½ or less at the interface.

10. The semiconductor device according to claim 7, wherein the first electrode further contains germanium, a concentration of germanium at the interface being half a maximum concentration of germanium in the first electrode.

11. The semiconductor device according to claim 1, wherein the second conductor contains indium tin oxide.

12. The semiconductor device according to claim 1, wherein the second electrode further includes
a fourth conductor that is provided on a lower surface and a side surface of the second conductor and contains nitrogen and titanium, and
a fifth conductor that is provided on a side surface of the fourth conductor and contains titanium.

13. The semiconductor device according to claim 12, wherein the third conductor contacts an upper surface of the first electrode and a lower surface of the fourth conductor.

14. The semiconductor device according to claim 12, wherein the fourth conductor and the fifth conductor further contain oxygen.

15. The semiconductor device according to claim 1, wherein the oxide semiconductor contains indium-gallium-zinc oxide.

16. The semiconductor device according to claim 1, wherein the oxide semiconductor and the insulating film are parts of a vertical transistor.

17. The semiconductor device according to claim 1, wherein the first electrode functions as an electrode of a capacitor.

18. A method of manufacturing a semiconductor device, the method comprising:
forming a hole in an insulator;
forming a first electrode containing silicon in the hole;
forming a second electrode; and
forming a cell transistor including an oxide semiconductor on an upper surface of the second electrode after forming the first electrode and the second electrode, wherein forming the second electrode includes
forming a first conductor containing metal and silicon above the first electrode, and
forming a second conductor above the first conductor.

19. The method of manufacturing a semiconductor device according to claim 18, wherein forming the first conductor includes
forming a third conductor that contacts an upper surface of the first electrode and contains the metal, and
performing heat treatment after forming the third conductor to change a part of the third conductor into the first conductor.

20. The method of manufacturing a semiconductor device according to claim 18, wherein forming the second electrode further includes forming a fourth conductor between the first conductor and the second conductor.
